(19) United States
(12) Patent Application Publication
(10) Pub. No.: US 2021/0206911 A1
(43) Pub. Date: Jul. 8, 2021

(54) POLYMER

(71) Applicant: Sumitomo Chemical Company Limited, Tokyo (JP)

(72) Inventors: Ruth Pegington, Godmanchester (GB); Martina Pintani, Godmanchester (GB)

(73) Assignee: Sumitomo Chemical Company Limited, Tokyo (JP)

(21) Appl. No.: 17/141,717

(22) Filed: Jan. 5, 2021

(30) Foreign Application Priority Data
Jan. 6, 2020 (GB) 2000092.3

(51) Int. Cl. C08G 61/10; H01L 51/00; H01L 51/50; G01N 15/14

(52) U.S. Cl. CPC C08G 61/10; H01L 51/0039; G01N 15/14; H01L 51/5092; H01L 51/5072

(57) ABSTRACT

A polymer having a first repeat unit of formula (I) and a second repeat unit of formula (II):

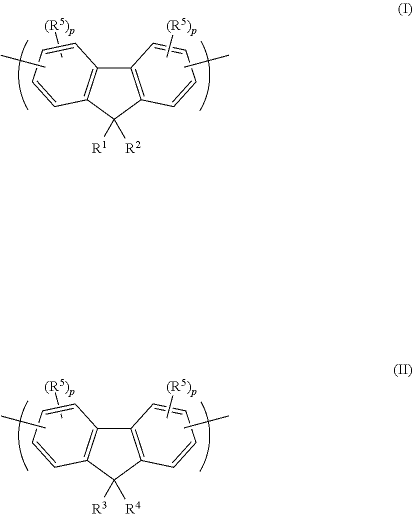

wherein: R¹ is an ionic substituent and R² is a substituent; R³ and R⁴ are each independently a non-ionic substituent; R⁵ independently in each occurrence is a substituent; and each p is independently 0, 1, 2 or 3. A layer of an organic electronic device, e.g. an electron-transporting or electron-injecting layer of an organic light-emitting device, may be formed by deposition of an ink containing the polymer dissolved in a solvent. A light-emitting marker for use in an assay may contain the polymer.

### RELATED APPLICATIONS

This application claims foreign priority benefits under 35 U.S.C. § 119(a)-(d) or 35 U.S.C. § 365(b) of British application number GB 2000092.3, filed Jan. 6, 2020, the entirety of which is incorporated herein.

### BACKGROUND

Embodiments of the present disclosure relate to polymers for forming a layer of an organic electronic device, electronic devices and inks containing said polymers and methods of forming electronic devices from said inks. And light-emitting markers comprising a polymer and a binding group for binding to a target analyte.

Electronic devices containing active organic materials include organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED includes an anode, a cathode and an organic light-emitting layer containing a light-emitting material between the anode and cathode.

In operation, holes are injected into the device through the anode and electrons are injected through the cathode. Holes in the highest occupied molecular orbital (HOMO) and electrons in the lowest unoccupied molecular orbital (LUMO) of the light-emitting material combine to form an exciton that releases its energy as light.

An electron-transporting or electron-injecting layer may be provided between the cathode and the light-emitting layer.

WO 2012/133229 discloses polymers substituted with certain cationic groups.

WO 2017/103609 discloses an OLED containing an electron-injection layer containing a charge-transfer complex of an acceptor material doped with an n-dopant in which the acceptor material is substituted with an ionic group.

### SUMMARY

A summary of aspects of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects and/or a combination of aspects that may not be set forth.

In some embodiments, there is provided a polymer having a first repeat unit of formula (I) and a second repeat unit of formula (II):

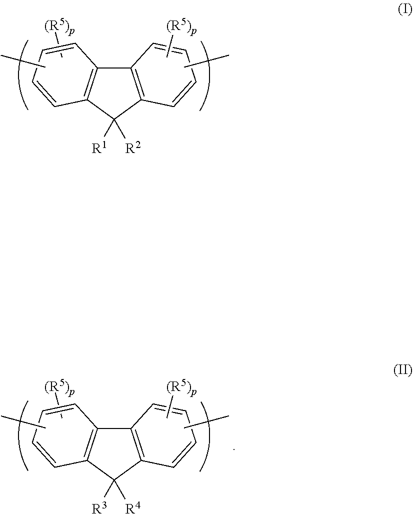

R¹ is an ionic substituent and R² is a substituent.

R³ and R⁴ are each independently a non-ionic substituent.

R⁵ independently in each occurrence may be a substituent.

Each p may be independently 0, 1, 2 or 3.

Optionally, R¹ is a group of formula (III):

-(Sp^{l})u-(A)v

wherein Sp¹ is a spacer group; A is an anion or cation; u is 0 or 1; v is 1 if u is 0; and v is at least 1 if u is 1, the polymer comprising one or more counterions B to balance the charge of the one or more anions or cations A.

Optionally, u is 1 and Sp¹ is an arylene or heteroarylene group Ar which may be substituted with one or more non-polar substituents.

In some embodiments, R² is an ionic group.

In some embodiments, R² is a non-ionic group.

Optionally, R³ and R⁴ are each independently a C₁₋₄₀ hydrocarbyl group.

Optionally, each p is 0.

Optionally, the repeat unit or repeat units of formula (I) form 50-99 mol % of the repeat units of the polymer.

Optionally, the repeat unit or repeat units of formula (II) form 1-50 mol % of the repeat units of the polymer.

In some embodiments there is provided an organic electronic device containing a polymer having a first repeat unit of formula (I) and a second repeat unit of formula (II).

Optionally, the organic electronic device contains adjacent first and second organic layers and wherein the second layer contains the polymer having a first repeat unit of formula (I) and a second repeat unit of formula (II).

Optionally, the organic electronic device is an organic light-emitting device in which the first organic layer is an organic light-emitting layer disposed between an anode and a cathode and the second organic layer is an electron-transporting layer or an electron-injecting layer disposed between the organic light-emitting layer and the cathode.

According to some embodiments there is provided an ink containing a polymer having a first repeat unit of formula (I) and a second repeat unit of formula (II) dissolved in a solvent.

Optionally, the solvent contains or consists of an alcohol, e.g. 2-butoxyethanol.

According to some embodiments there is a method of forming an organic electronic device having first and second organic layers as described herein wherein formation of the second organic layer includes deposition of an ink as described herein onto the first organic layer and evaporation of the solvent.

According to some embodiments, there is provided a light-emitting marker comprising a polymer as described herein and a binding group for binding to a target analyte.

Optionally, the light-emitting marker is a light-emitting particle comprising the polymer and a matrix material.

Optionally, the light-emitting marker comprises a biomolecule binding group.

According to some embodiments, there is provided an assay method for determining the presence and/or concentration of a target analyte. The assay method comprises contacting a sample with a light-emitting marker as described herein; irradiating the light-emitting marker with light of at least one peak wavelength; and measuring a luminance of the light-emitting marker.

Optionally, the sample contacted with the light-emitting composition is analysed by flow cytometry.

Optionally, the target analyte is a cell.

### DESCRIPTION OF THE DRAWINGS

The present disclosure is described in conjunction with the appended figures. It is emphasized that, in accordance with the standard practice in the industry, various features are not drawn to scale. In fact, the dimensions of the various features may be arbitrarily increased or reduced for clarity of discussion.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 illustrates schematically an OLED according to some embodiments of the present disclosure.

### DETAILED DESCRIPTION

An organic layer of an organic electronic device may be formed by depositing an ink containing materials for forming that layer.

Formation of a layer of an organic electronic device which includes deposition of an ink onto a first organic layer in order to form a second, adjacent organic layer requires that the first layer is not significantly affected by the solvent or solvents of the ink, e.g. a significant amount of the first layer should not be dissolved by the solvent(s) of the ink used in formation of the second layer. This may be achieved by selecting materials for adjacent layers which have different solubilities, e.g. an ink containing an active material dissolved in a polar solvent may be deposited onto a layer containing a material or materials which are sparingly soluble or insoluble in the polar solvent of the ink.

However, the present inventors have found that use of an ink to form adjacent polar and non-polar layers can result in poor device performance.

The present inventors have surprisingly found that performance of such a device may be improved by including a polymer containing a first repeat unit with one or more ionic substituents and a second repeat unit without any ionic substituents. Accordingly, in some embodiments, polymers as described herein may be provided in a layer of an organic electronic device.

In some embodiments, polymers as described herein may be used as a light-emitting polymer of a light-emitting marker for detection of a target analyte.

### Ionic Substituents

Exemplary ionic substituents have formula (III):

-(Sp¹)u-(A)v (III)

wherein Sp¹ is a spacer group; A is an anion or cation; u is 0 or 1; v is 1 if u is 0; and v is at least 1, preferably 1, if u is 1, the polymer further comprising one or more counterions B to balance the charge of the one or more anions or cations A.

Optionally, Sp¹ is selected from:

C₁₋₁₂ alkylene wherein one or more non-adjacent C atoms may be replace with O, S, C═O, COO or phenylene; and

an arylene or heteroarylene group Ar, preferably phenylene, that may be unsubstituted or substituted with one or more C₁₋₂₀ alkyl groups wherein one or more non-adjacent, non-terminal C atoms of the C₁₋₂₀ alkyl groups may be replaced with O, S, C═O or COO.

By “non-terminal C atom” of an alkyl or alkylene group as used anywhere herein is meant an atom of an alkyl or alkylene group other than the methyl group of a n-alkyl; the methyl groups at the ends of a branched alkyl chain; or the methyl group or groups of a branched alkylene.

“alkylene” as used anywhere herein means a divalent carbon atom or divalent alkyl chain.

In some embodiments, u is 1; Sp¹ is a C₁₋₁₂ alkylene or unsubstituted or substituted phenylene; and v is 1.

A of formula (III) and B may have the same valency, with a counterion B balancing the charge of each A of formula (III).

Anion or cation A may be monovalent or polyvalent.

Preferably, A and B are each monovalent.

In another embodiment, the organic semiconductor may comprise a plurality of anions or cations A, preferably monovalent anions or cations A, wherein the charge of two or more anions or cations A is balanced by a single, polyvalent counterion B. Optionally, the organic semiconductor comprises one or more di- or trivalent cations B.

Exemplary anions A may be selected from, without limitation, sulfonate and —COO⁻. A preferred anion A is —COO⁻.

Exemplary cations A may be selected from organic or inorganic cations including, without limitation —N(R¹¹)₃+; —P(R¹¹)₃⁺; S(R¹¹)₂⁺; or a heteroaromatic cation, optionally a heteroaromatic cation comprising or consisting of C and N atoms optionally pyridinium or imidazolium wherein R¹¹ in each occurrence is H or C₁₋₁₂ hydrocarbyl, optionally C₁₋₁₂ alkyl. A preferred cation A is —NR¹¹₃⁺.

Cation B is optionally a metal cation, optionally Li⁺, Na⁺, K⁺, Cs⁺, preferably Cs⁺, or an organic cation, optionally N(R¹¹)₄⁺ such as tetraalkylammonium, or a heteroaromatic cation optionally ethylmethyl imidazolium or pyridinium. The size of the cation may affect the dopant strength of the n-dopant. Preferably, the cation is an organic cation or a metal cation from the third or higher periods of the Periodic Table, preferably fourth or higher periods, more preferably fifth or higher periods of the Periodic Table.

Anion B is optionally halide, optionally F-, Cl-, Br- or I-; hydroxide; a borate, optionally BF₄⁻; a phosphate, optionally PF₆⁻; a phosphinate; a phosphonate; an imide, optionally TFSI; or a sulfonate group, optionally mesylate, tosylate or sulfonate.

A substituent comprising an ester group may be converted to a substituent comprising ionic group —COO⁻B⁺. The conversion may be as described in WO 2012/133229, the contents of which are incorporated herein by reference.

### Non-Ionic Substituents

Non-ionic substituents as described herein may each independently be selected from the group consisting of:

alkyl, optionally C₁₋₂₀ alkyl, wherein one or more non-adjacent, non-terminal C atoms may be replaced with a group selected from O, S, C═O or COO and one or more H atoms may be replaced with F; and

a group of formula -(Ak)ₘ-(Ar²)ₙ wherein Ak is an alkylene group, optionally a C₁₋₁₂ alkylene group, in which one or more non-adjacent, non-terminal C atoms may be replaced with a group selected from O, S, C═O or COO; m is 0 or 1; Ar² in each occurrence is independently a C₆₋₂₀ aryl or 5-20 membered heteroaryl group that is unsubstituted or substituted with one or more substituents; and n is at least 1, optionally 1, 2 or 3.

Optionally, Ar² is phenyl.

Substituents of Ar², where present, may be selected from F; CN; and C₁₋₁₂ alkyl, wherein one or more non-adjacent, non-terminal C atoms may be replaced with a group selected from O, S, C═O or —COO and one or more H atoms of the alkyl may be replaced with F.

In some embodiments, the non-ionic substituents described herein are C₁₋₄₀ hydrocarbyl groups, optionally C₁₋₂₀ alkyl; and an aromatic group, e.g. phenyl or biphenyl, which is unsubstituted or substituted with one or more C₁₋₁₂ alkyl groups.

### First and Second Repeat Units

The polymer may be a conjugated polymer. By “conjugated polymer” is meant a polymer comprising repeat units in the polymer backbone, e.g. first and/or second repeat units in the polymer backbone, that are directly conjugated to adjacent repeat units in the polymer backbone.

The first repeat unit and second repeat unit of the polymer may have the same backbone group. The first repeat unit and second repeat unit may both be a C₆₋₂₀ arylene repeat unit, optionally a repeat unit selected from fluorene, phenylene, naphthalene, anthracene, indenofluorene, phenanthrene and dihydrophenanthrene repeat units.

The polymer may contain only one first repeat unit. The polymer may contain two or more different first repeat units.

The polymer may contain only one second repeat unit. The polymer may contain two or more different second repeat units.

The first repeat unit may have formula (I):

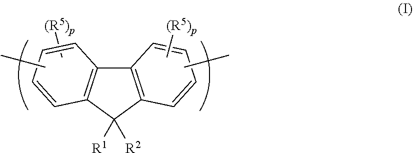

wherein

R¹ is an ionic substituent and R² is a substituent;

R⁵ independently in each occurrence is a non-ionic substituent, optionally a C₁₋₄₀ hydrocarbyl group; and

each p is independently 0, 1, 2 or 3.

R¹ may be selected from groups of formula (III) as described above.

R² may be selected from ionic or non-ionic groups, optionally ionic or non-ionic groups as described above.

In some embodiments, R² is an ionic group. In some embodiments, R¹ and R² are the same.

In some embodiments, R² is a non-ionic group. In some embodiments, R² is a C₁₋₄₀ hydrocarbyl group.

Exemplary repeat units of formula (I) are:

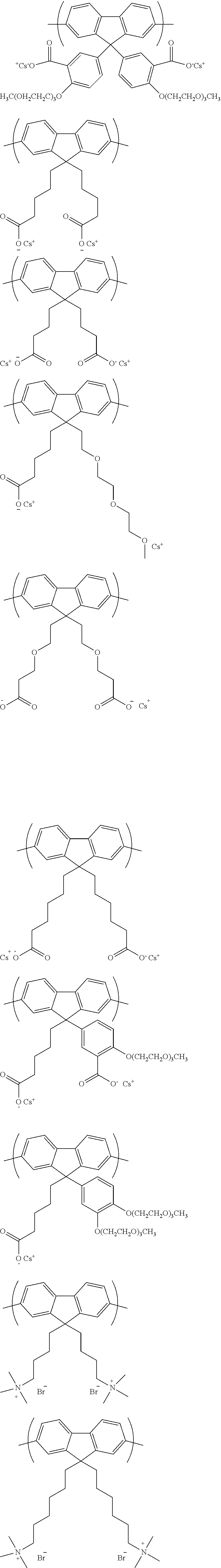

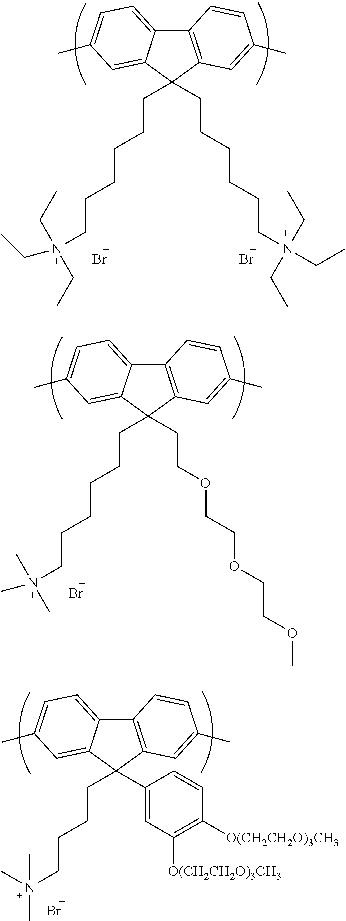

The second repeat unit may have formula (II):

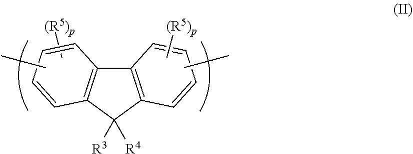

wherein

R³ and R⁴, which may be the same or different in each occurrence, are each a non-ionic substituent;

R⁵ independently in each occurrence is a non-ionic substituent, optionally a C₁₋₄₀ hydrocarbyl group; and

each p is independently 0, 1, 2 or 3.

In some embodiments, R³ and R⁴ are each independently a C₁₋₄₀ hydrocarbyl group, optionally a C₁₋₂₀ alkyl, unsubstituted phenyl or phenyl substituted with one or more C₁₋₁₂ alkyl groups.

In some embodiments, the repeat units of the polymer consist of one or more repeat units of formula (I) and one or more repeat units of formula (II).

In some embodiments, the polymer contains one or more repeat units other than repeat units of formulae (I) or (II). Other repeat units may be selected from, without limitation, a C₆₋₂₀ arylene repeat unit other than a fluorene unit; a repeat unit containing one or more 5-20 membered heteroarylene groups, and arylamine repeat units, each of which may be unsubstituted or substituted with one or more substituents, optionally one or more non-ionic substituents, optionally one or more non-ionic substituents selected from F, CN and non-ionic substituents as described above.

Exemplary heteroarylene co-repeat units include repeat units of formulae (VIII), (IX) and (X):

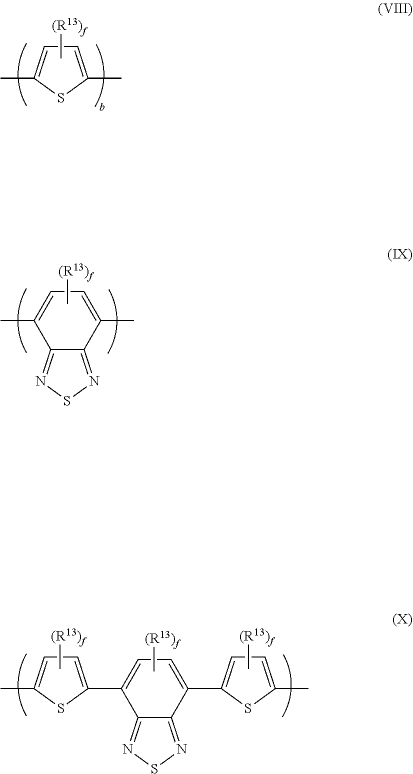

wherein R¹³ in each occurrence is independently an ionic or non-ionic substituent as described anywhere herein and f is 0, 1 or 2.

Preferably, each R¹³ is independently selected from F, CN and C₁₋₂₀ alkyl wherein one or more non-adjacent, non-terminal C atoms are replaced with phenylene, O, S, COO or CO; and phenyl which may be unsubstituted or substituted by one or more C₁₋₂₀ alkyl groups wherein one or more non-adjacent, non-terminal C atoms are replaced with phenylene, O, S, COO or CO.

In the case where the polymer is a light-emitting polymer of a light-emitting marker, the polymer may comprise one or more repeat units other than formulae (I) and (II) according to a desired light emission or light absorption of the light-emitting polymer.

Exemplary arylamine repeat units have formula (XI):

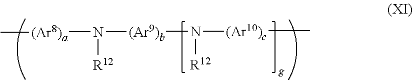

wherein Ar⁸, Ar⁹ and Ar¹⁰ in each occurrence are independently selected from substituted or unsubstituted aryl or heteroaryl, R¹² independently in each occurrence is a substituent;

g is 0, 1 or 2, preferably 0 or 1, and a, b and c are each independently 1, 2 or 3.

R¹², which may be the same or different in each occurrence when g is 1 or 2, is preferably selected from the group consisting of alkyl, optionally C₁₋₂₀ alkyl, Ar¹¹ and a branched or linear chain of Ar¹¹ groups wherein Ar¹¹ in each occurrence is independently substituted or unsubstituted aryl or heteroaryl.

Any two aromatic or heteroaromatic groups selected from Ar⁸, Ar⁹, and, if present, Ar¹⁰ and Ar¹¹ that are directly bound to the same N atom may be linked by a direct bond or a divalent linking atom or group. Preferred divalent linking atoms and groups include O, S; substituted N; and substituted C.

Ar⁸ and Ar¹⁰ are preferably C₆₋₂₀ arylene, more preferably phenylene, that may be unsubstituted or substituted with one or more substituents, optionally one or more substituents selected from ionic and non-ionic substituents R¹³.

In the case where g=0, Ar⁹ is preferably C₆₋₂₀ aryl, more preferably phenylene, that may be unsubstituted or substituted with one or more substituents.

In the case where g=1, Ar⁹ is preferably C₆₋₂₀ arylene, more preferably phenylene or a polycyclic arylene group, for example naphthalene, perylene, anthracene or fluorene, that may be unsubstituted or substituted with one or more substituents.

R¹² is preferably Ar¹¹ or a branched or linear chain of Ar¹¹ groups. Ar¹¹ in each occurrence is preferably phenyl that may be unsubstituted or substituted with one or more substituents.

Exemplary groups R¹² include the following, each of which may be unsubstituted or substituted with one or more substituents, and wherein * represents a point of attachment to N:

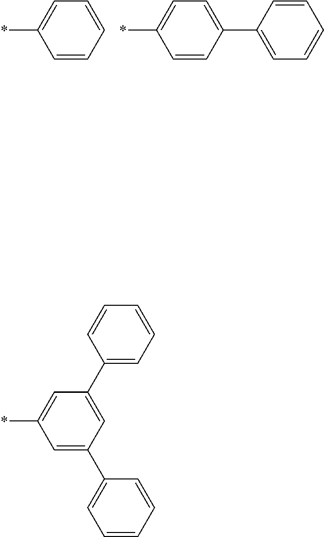

a, b and c are preferably each 1.

Ar⁸, Ar⁹, and, if present, Ar¹⁰ and Ar¹¹ are each independently unsubstituted or substituted with one or more, optionally 1, 2, 3 or 4, substituents.

Substituents may independently be a group R¹³ as described above.

Preferred substituents of Ar⁸, Ar⁹, and, if present, Ar¹⁰ and Ar¹¹ are C₁₋₄₀ hydrocarbyl, preferably C₁₋₂₀ alkyl.

Preferred repeat units of formula (XI) include unsubstituted or substituted units of formulae (XI-1), (XI-2) and (XI-3):

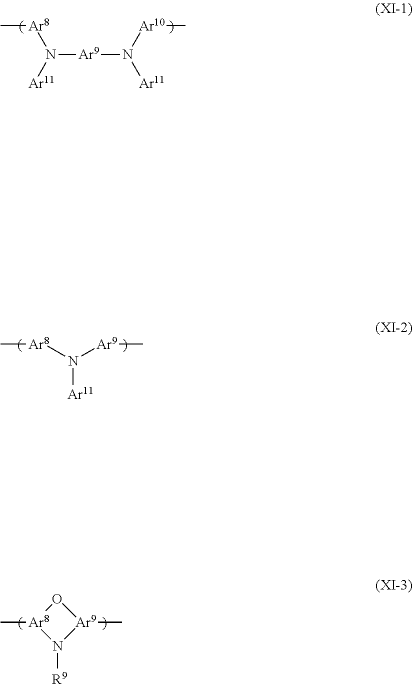

The C₆₋₂₀ arylene repeat unit other than a fluorene may be selected from, without limitation a phenylene, naphthalene, anthracene, indenofluorene, phenanthrene and dihydrophenanthrene repeat unit.

Optionally, the repeat unit or repeat units of formula (I) form 50-99 mol %, optionally 60-95 mol %, of the repeat units of the polymer.

Optionally, the repeat unit or repeat units of formula (II) form 1-50 mol %, optionally 5-40 mol %, of the repeat units of the polymer.

The polymer may have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of a semiconducting polymer as described anywhere herein may be 1×10³ to 1×10⁸, and preferably 1×10⁴ to 1×10⁷.

### OLED

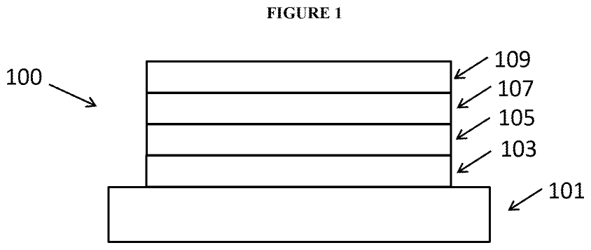

FIG. 1, which is not drawn to any scale, illustrates an OLED 100 according to some embodiments. The OLED is supported on a substrate 101, for example a glass or plastic substrate. The substrate may be flexible.

The OLED 100 comprises a light-emitting layer 105 disposed between an anode 103 and a cathode 109 and an electron transporting or electron-injecting layer 107 disposed between the light-emitting layer 105 and the cathode 109 and directly adjacent to the light-emitting layer 105.

The anode 103 may be single layer of conductive material or may be formed from two or more conductive layers. Anode 103 may be a transparent anode, for example a layer of indium-tin oxide. A transparent anode 103 and a transparent substrate 101 may be used such that light is emitted through the substrate. The anode may be opaque, in which case the substrate 101 may be opaque or transparent, and light may be emitted through a transparent cathode 109.

Light-emitting layer 105 contains at least one light-emitting material. Light-emitting material 105 may consist of a single light-emitting compound or may be a mixture of more than one compound, optionally a host doped with one or more light-emitting dopants. Light-emitting layer 105 may contain at least one light-emitting material that emits phosphorescent light when the device is in operation, or at least one light-emitting material that emits fluorescent light when the device is in operation. Light-emitting layer 105 may contain at least one phosphorescent light-emitting material and at least one fluorescent light-emitting material.

Electron-transporting or injecting layer 107 comprises or consists of a polymer as described herein.

Cathode 109 is formed of at least one layer, optionally two or more layers, for injection of electrons into the device.

In some embodiments, the cathode 109 is in direct contact with the electron-transporting layer 107.

The polymer of layer 107 according to the embodiment of FIG. 1 is an electron-transporting polymer. Preferably, the electron-transporting polymer has a lowest unoccupied molecular orbital (LUMO) that is no more than about 1 eV, optionally less than 0.5 eV or 0.2 eV, deeper (i.e. further from vacuum) than a LUMO of a material of the light-emitting layer, which may be a LUMO of a light-emitting material or a LUMO of a host material if the light-emitting layer comprises a mixture of a host material and a light-emitting material.

Optionally, the electron-transporting polymer has a LUMO of less (i.e. closer to vacuum) than 3.0 eV from vacuum level, optionally around 2.1 to 2.8 eV from vacuum level.

LUMO levels as described herein are as measured by square wave voltammetry.

Layer 107 may be an electron transporting layer which comprises or consists of the undoped electron-transporting polymer.

Layer 107 may be an electron injecting layer in which the electron-transporting polymer is doped with an n-dopant. The n-doped electron-transporting polymer may be an extrinsic or degenerate semiconductor.

Optionally, the doped organic semiconductor has a work function that is about the same as a LUMO of a material of the light-emitting layer.

The OLED 100 may contain one or more further layers between the anode 103 and the cathode 109, for example one or more charge-transporting, charge-blocking or charge-injecting layers.

In some embodiments, the device comprises a hole-injection layer comprising a conducting material between the anode 103 and the light emitting layer 105.

In some embodiments, the device comprises a hole-transporting layer comprising a semiconducting hole-transporting material between the anode 103 and the light emitting layer 105.

### Ink

In some embodiments, formation of a second layer of an organic electronic device, for example an electron-transporting or electron-injecting layer of an OLED, may include deposition of an ink comprising the polymer dissolved in a solvent onto a first layer, for example a light-emitting layer of an OLED. In the case of an electron injecting layer, an n-dopant or precursor thereof may be dissolved therein. An n-dopant precursor in the ink may be activated after deposition of the ink and during and/or after evaporation of the solvent material(s) to form an electron injecting layer comprising the polymer doped by an n-dopant formed upon activation of the n-dopant precursor.

The solvent may be a single solvent material. The solvent may be a mixture of two or more solvent materials.

Optionally, the solvent comprises or consists of an alcohol. Exemplary alcohols are monohydric C₁₋₁₀ alkyl alcohols and mono-C₁₋₁₀ ethers of C₁₋₁₀ alkylene diols, for example methanol ethanol, propanol, 2-butoxyethanol and ethylene glycol.

Formation of the first layer may comprise deposition of the materials of the first layer, or precursors thereof, by any suitable method, for example thermal evaporation or solution deposition. In some embodiments, formation of the first layer comprises deposition of the materials of the first layer, or precursors thereof, dissolved or dispersed in a solvent. The solvent may comprise or consist of one or more non-polar aprotic solvent materials.

Optionally, a non-polar aprotic solvent material as described herein has a dielectric constant at 20° C. of less than 5, optionally less than 4. Optionally, the non-polar aprotic solvent material has a dielectric constant of between 3 and 4.

In some embodiments, the one or more non-polar aprotic solvents are selected from benzenes substituted with one or more substituents selected from C₁₋₆ alkyl and C₁₋₆ alkoxy groups, for example toluene, xylenes and methylanisoles, and mixtures thereof. Optionally, the non-polar solvent is a benzene substituted with at least one C₁₋₆ alkoxy group.

In some embodiments, formation of the organic light-emitting layer comprises depositing a formulation comprising the material or materials of the organic light-emitting layer dissolved or dispersed in a solvent comprising one or more non-polar solvents.

Particularly preferred solution deposition techniques including printing and coating techniques such spin-coating, dip-coating, slot die coating, roll printing, screen printing, inkjet printing and lithographic printing.

n-dopant

The polymer may be n-doped by an n-dopant.

An electron-injecting layer may comprise or consist of the charge-transfer salt formed by n-doping of the polymer.

In forming an electron-injecting layer, the ink containing the polymer and an n-dopant precursor may be deposited in air.

n-doping may be effected by activation of the n-dopant precursor following deposition thereof. In some embodiments, n-doping is effected after formation of a cathode over the layer containing the organic semiconductor and n-dopant precursor, and optionally after encapsulation.

Activation may be by excitation of the n-dopant and/or the organic semiconductor.

Exemplary activation methods are thermal treatment and irradiation.

Optionally, thermal treatment is at a temperature in the range 80° C. to 170° C., preferably 120° C. to 170° C. or 130° C. to 160° C.

Thermal treatment and irradiation as described herein may be used together.

For irradiation, any wavelength of light may be used, for example a wavelength having a peak in the range of about 200-700 nm.

The light emitted from the light source suitably overlaps with an absorption feature, for example an absorption peak or shoulder, of the n-dopant precursor's or the organic semiconductor's absorption spectrum. Optionally, the light emitted from the light source has a peak wavelength within 25 nm, 10 nm or 5 nm of an absorption maximum wavelength of the organic semiconductor or n-dopant precursor, however it will be appreciated that a peak wavelength of the light need not coincide with an absorption maximum wavelength of the organic semiconductor or n-dopant precursor.

In one embodiment, the n-dopant has formula (IV):

(Core)p-(X)q (VI)

wherein Core is a core group; p is 0 and q is 1, or p is 1 and q is at least 1; and X is a group of formula (V):

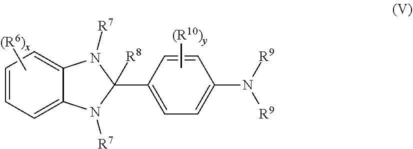

wherein:

R⁶, R⁷, R⁸, R⁹ and R¹⁰ are each independently H or a substituent;

x and y are each independently 0, 1, 2, 3 or 4; and

one of R⁶-R¹⁰ is a direct bond or divalent linking group linking the group of formula (VII) to Core in the case where n is 1.

Optionally, the compound of formula (IV) is substituted with at least one ionic substituent. The or each ionic substituent may be selected from ionic substituents of formula (III) as described above.

The compound of formula (IV) may comprise one or more non-ionic substituents, optionally C₁₋₂₀ alkyl wherein one or more non-adjacent, non-terminal C atoms are replaced with phenylene, O, S, COO or CO; and phenyl which may be unsubstituted or substituted by one or more C₁₋₂₀ alkyl groups wherein one or more non-adjacent, non-terminal C atoms are replaced with phenylene, O, S, COO or CO.

Preferably, R⁷ is C₁₋₁₂ alkyl.

Preferably, R⁸ is H.

R¹⁰, if present, is optionally a C₁₋₂₀ hydrocarbyl group. Preferably, y is 0.

In the case where n=0, the group of formula (V) is a compound and at least one occurrence of at least one of R⁶-R¹⁰, preferably at least one occurrence of at least one of R⁶ and R⁹, is an ionic group.

The or each non-ionic group R⁶-R¹⁰ is optionally selected from H and C₁₋₄₀ hydrocarbyl, optionally H, C₁₋₁₂ alkyl and C₆₋₂₀ aryl, optionally phenyl, that is unsubstituted or substituted with one or more C₁₋₁₂ alkyl groups.

In the case where n is 1, one of R⁶-R¹⁰ is a direct bond or divalent linking group linking the group of formula (V) to Core. The divalent linking group of the or each group of formula (V) is optionally selected from unsubstituted or substituted phenylene and C₁₋₁₂ alkylene wherein one or more non-adjacent C atoms of the alkylene may be replaced with O, S, CO or COO and one or more C atoms may be replaced with unsubstituted or substituted aryl or heteroaryl. Optionally, aryl or heteroaryl groups of the divalent linking group are selected from phenylene and 5 or 6 membered heteroarylene groups. Substituents of aryl or heteroaryl groups are optionally selected from C₁₋₁₂ alkyl.

Exemplary linking groups are phenylene; C₁₋₁₂ alkylene; phenylene-C₁₋₁₂ alkylene; and phenoxy-C₁₋₁₂ alkylene wherein each phenylene group may be unsubstituted or substituted with one or more C₁₋₁₂ alkyl groups.

### Light-Emitting Layer

The OLED 100 may contain one or more light-emitting layers.

Light-emitting materials of the OLED 100 may be fluorescent materials, phosphorescent materials or a mixture of fluorescent and phosphorescent materials. Light-emitting materials may be selected from polymeric and non-polymeric light-emitting materials. Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12 1737-1750, 2000, the contents of which are incorporated herein by reference. A conjugated polymer as described herein may comprise one or more repeat units selected from formulae (I)-(IV) described above. In some embodiments, the light-emitting polymer may comprise one or more arylene repeat units, optionally one or more repeat units selected from formulae (I)-(IV), and one or more repeat units selected from heteroarylene repeat units and amine repeat units. Optionally, heteroarylene repeat units and amine repeat units are selected from repeat units as described in WO 99/54385, WO 00/46321, WO 2004/060970 and WO 2005/049546, the contents of which are incorporated herein by reference.

Light-emitting layer 105 may comprise a host material and a fluorescent or phosphorescent light-emitting dopant. Exemplary phosphorescent dopants are row 2 or row 3 transition metal complexes, for example complexes of ruthenium, rhodium, palladium, rhenium, osmium, iridium, platinum or gold.

A fluorescent light-emitting layer may consist of a light-emitting material alone or may further comprise one or more further materials, for example a triplet-accepting material such as a triplet-accepting polymer as described in WO 2013/114118, the contents of which are incorporated herein by reference.

A light-emitting layer of an OLED may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

A light-emitting layer may contain a mixture of more than one light-emitting material, for example a mixture of light-emitting materials that together provide white light emission. In some embodiments, a white light-emitting layer may comprise a white light-emitting polymer.

In some embodiments, a plurality of light-emitting layers may together produce white light.

A white-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K.

In some embodiments, one or more materials of the organic light-emitting layer are substituted with substituents for dissolution in a non-polar solvent. Exemplary substituents are selected from C₁₋₄₀ hydrocarbyl groups, optionally C₁₋₂₀ alkyl; unsubstituted phenyl; phenyl substituted with one or more C₁₋₂₀ alkyl groups. In some embodiments, at least 80%, optionally at least 90%, at least 95% or 100% of the total number of substituents of a material of the light-emitting layer, preferably a light-emitting material or a host material, are hydrocarbyl groups.

In some embodiments, the light-emitting layer comprises a light-emitting polymer or a polymeric host material and a light-emitting material wherein at least 80% of the total number of substituents of a material of the light-emitting layer, preferably a light-emitting material or a host material, are hydrocarbyl groups.

### Cathode

The cathode may comprise one or more layers.

In some embodiments, the cathode of an OLED comprising an electron transporting layer comprises or consists of a conductive layer in direct contact with the electron transporting layer or spaced apart therefrom by a thin (e.g. 1-5 nm) layer of metal compound.

Exemplary metal compounds are an oxide or fluoride of an alkali or alkali earth metal, for example lithium fluoride.

In some embodiments, the cathode of an OLED comprising an electron injecting layer comprises or consists of a conductive layer in direct contact with the electron injecting layer.

In some embodiments, the cathode of an OLED as described herein comprises a plurality of conductive layers.

The or each conductive layer of a cathode may comprise one or more conductive materials. Exemplary conductive materials are metals, preferably metals having a work function of at least 4 eV, optionally aluminium, copper, silver or gold and iron.

Exemplary non-metallic conductive materials include conductive metal oxides, for example indium tin oxide and indium zinc oxide, graphite and graphene.

Work functions of metals are as given in the CRC Handbook of Chemistry and Physics, 12-114, 87^{th} Edition, published by CRC Press, edited by David R. Lide. If more than one value is given for a metal then the first listed value applies.

### Hole-Transporting Layer

A hole transporting layer may be provided between the anode 103 and the light-emitting layer 105.

The hole-transporting layer may be cross-linked, particularly if an overlying layer is deposited from a solution. The crosslinkable group used for this crosslinking may be a crosslinkable group comprising a reactive double bond such and a vinyl or acrylate group, or a benzocyclobutane group. Crosslinking may be performed by thermal treatment, preferably at a temperature of less than about 250° C., optionally in the range of about 100-250° C.

A hole transporting layer may comprise or may consist of a hole-transporting polymer, which may be a homopolymer or copolymer comprising two or more different repeat units. The hole-transporting polymer may be conjugated or non-conjugated. Exemplary conjugated hole-transporting polymers are polymers comprising arylamine repeat units, for example as described in WO 99/54385 or WO 2005/049546 the contents of which are incorporated herein by reference. Conjugated hole-transporting copolymers comprising arylamine repeat units may have one or more co-repeat units selected from arylene repeat units, for example one or more repeat units selected from fluorene, phenylene, phenanthrene naphthalene and anthracene repeat units, each of which may independently be unsubstituted or substituted with one or more substituents, optionally one or more C₁₋₄₀ hydrocarbyl substituents.

A hole-transporting layer may consist essentially of a hole-transporting material or may comprise one or more further materials. A light-emitting material, optionally a phosphorescent material, may be provided in the hole-transporting layer. Emission from a light-emitting hole-transporting layer and emission from light-emitting layer 105 may combine to produce white light.

### Hole Injection Layers

A conductive hole injection layer, which may be formed from a conductive organic or inorganic material, may be provided between the anode 103 and the light-emitting layer 105 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. Nos. 5,723,873 and 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### Light-Emitting Marker

A light-emitting marker, e.g. for use in an assay, may comprise or consist of a polymer as described herein.

In some embodiments, the light-emitting marker is a polymer as described herein wherein the polymer comprises a binding group for binding (directly or indirectly) to a target analyte, optionally a biomolecule binding group. An assay formulation may comprise the light-emitting polymer marker dissolved or dispersed in one or more liquid.

In some embodiments, the light-emitting marker may be in the form of a light-emitting particles comprising or consisting of a light-emitting polymer as described herein and a matrix.

In some embodiments, the particle comprises the light-emitting polymer distributed through the matrix, optionally homogenously distributed through the matrix.

In some embodiments, the particle comprises a core comprising or consisting of the light-emitting polymer and a shell comprising or consisting of the matrix.

The matrix may be inorganic. The inorganic matrix may be an oxide, optionally silica, alumina or titanium dioxide.

In some embodiments, the matrix is covalently bound to the light-emitting polymer. Preferably, the matrix is not covalently bound to the light-emitting polymer; in this case, there is no need for the matrix material and/or the light-emitting polymer to be substituted with reactive groups for forming such covalent bonds, e.g. during formation of the particles.

In some embodiments, a silica matrix as described herein may be formed by polymerisation of a silica monomer in the presence of the light-emitting polymer.

In some embodiments, the polymerisation comprises bringing a solution of silica monomer into contact with an acid or a base. The acid or base may be in solution. The light-emitting polymer may be in solution with the acid or base and/or the silica monomer before the solutions are mixed. Optionally, the solvents of the solutions are selected from water, one or more C₁₋₈ alcohols or a combination thereof.

Polymerising a matrix monomer in the presence of a light-emitting polymer may result in one or more chains of the polymer encapsulated within the particle and/or one or more chains of the polymer extending through a particle.

The particles may be formed in a one-step polymerisation process.

Optionally, the silica monomer is an alkoxysilane, preferably a trialkoxy or tetra-alkoxysilane, optionally a C₁₋₁₂ trialkoxy or tetra-alkoxysilane, for example tetraethyl orthosilicate. The silica monomer may be substituted only with alkoxy groups or may be substituted with one or more groups.

In some embodiments, a biomolecule binding group is bound to a surface of the particle, preferably to the matrix at the surface of the particle. The biomolecule binding group may be bound directly to the surface of the particle or bound through a surface binding group. The surface binding group may comprise polar groups. Optionally, the surface binding group comprises a polyether chain. By “polyether chain” as used herein is meant a chain having two or more ether oxygen atoms.

Silica at the surface of the particles may be reacted to form a group at the surface capable of binding to a biomolecule binding group. Optionally, silica at the surface is reacted with a siloxane.

The biomolecule binding group may be selected according to a target biomolecule to be detected. The biomolecule binding group may bind directly to the target biomolecule, or through a binding agent having an affinity for the biomolecule.

Target biomolecules include without limitation DNA, RNA, peptides, carbohydrates, antibodies, antigens, enzymes, proteins and hormones.

A preferred biomolecule binding group is biotin. In some embodiments, the biotin biomolecule binding group binds directly to a target analyte.

In some embodiments, the biotin biomolecule binding group when in use is bound to a protein having a plurality of biotin binding sites, preferably streptavidin, neutravidin, avidin or a recombinant variant or derivative thereof, and a biotinylated biomolecule having a second biotin group bound to the same protein, the protein and the biotinylated biomolecule together forming a binding agent for binding the target analyte to the biomolecule binding group. The biotinylated biomolecule may be selected according to the target analyte. The biotinylated biomolecule may comprise an antigen binding fragment, e.g. an antibody, which may be selected according to a target antigen.

Preferably, the particles have a number average diameter of no more than 5000 nm, more preferably no more than 2500 nm, 1000 nm, 900 nm, 800 nm, 700 nm, 600 nm, 500 nm or 400 nm as measured by dynamic light scattering (DLS) using a Malvern Zetasizer Nano ZS. Preferably the particles have a number average diameter of between 5-5000 nm, optionally 10-1000 nm, preferably between 10-500 nm, most preferably between 10-100 nm as measured by a Malvern Zetasizer Nano ZS.

Preferably, at least 50 wt % of the total weight of the particle consists of matrix material. Preferably at least 60, 70, 80, 90, 95, 98, 99, 99.5, 99.9 wt % of the total weight of the particle consists of matrix material.

In some embodiments, the particles may be stored in a dry, optionally lyophilised, form.

The particles may be provided as a colloidal suspension comprising the particles suspended in a liquid. Preferably, the particles form a uniform (non-aggregated) colloid in the liquid.

A liquid in which a light-emitting marker as described herein may be dissolved or dispersed is preferably selected from water, C₁₋₈ alcohols and mixtures thereof. The liquid may be a solution comprising salts dissolved therein, optionally a buffer solution.

### Applications

Polymers have been described herein in electron-transporting or electron-injecting layers of an OLED, however it will be appreciated that the polymers described herein may be used to form a layer of other organic electronic device, for example as an electron-extraction layer of an organic photovoltaic device or organic photodetector; as an auxiliary electrode layer of a n-type organic thin film transistor; or as an n-type semiconductor in a thermoelectric generator.

A light-emitting marker comprising a polymer as described herein may be used as a luminescent probe in an immunoassay such as a lateral flow or solid state immunoassay.

Optionally the light emitting polymers are for use in fluorescence microscopy or flow cytometry.

Optionally, in use the light-emitting marker is irradiated by light of two or more different wavelengths, e.g. wavelengths including at least two of 355, 405, 488, 562 and 640 nm.

In some embodiments, dissolved light-emitting polymer marker is brought into contact with a sample to be analysed.

In some embodiments, particles containing the light-emitting polymer, for example the particles in a colloidal suspension, are brought into contact with a sample to be analysed.

The description above provides preferred exemplary embodiment(s) only, and is not intended to limit the scope, applicability or configuration of the invention. Rather, the ensuing description of the preferred exemplary embodiment(s) will provide those skilled in the art with an enabling description for implementing a preferred exemplary embodiment of the invention, it being understood that various changes may be made in the function and arrangement of elements, including combinations of features from different embodiments, without departing from the scope of the invention.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the description above, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

1. A polymer comprising a first repeat unit of formula (I) and a second repeat unit of formula (II): 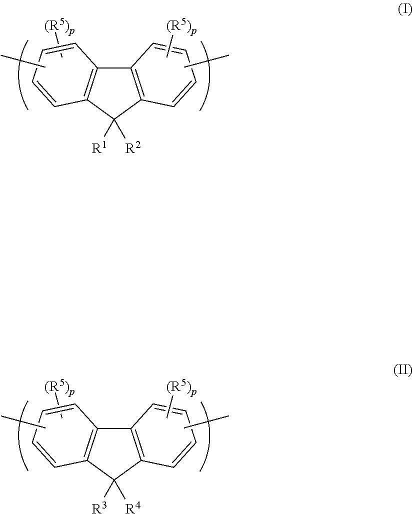
wherein
R¹ is an ionic substituent and R² is a substituent;
R³ and R⁴ are each independently a non-ionic substituent;
R⁵ independently in each occurrence is a substituent; and
each p is independently 0, 1, 2 or 3.

2. A polymer according to claim 1 wherein R¹ is a group of formula (III):
-(Sp¹)u-(A)v (III)
wherein Sp¹ is a spacer group; A is an anion or cation; u is 0 or 1; v is 1 if u is 0; and v is at least 1 if u is 1, the polymer comprising one or more counterions B to balance the charge of the one or more anions or cations A.

3. A polymer according to claim 2 wherein u is 1 and Sp¹ is an arylene or heteroarylene group Ar¹ which may be substituted with one or more non-polar substituents.

4. A polymer according to claim 1 wherein R² is an ionic group.

5. A polymer according to claim 1 wherein R² is a non-ionic group.

6. A polymer according to claim 1 wherein R³ and R⁴ are each independently a C₁₋₄₀ hydrocarbyl group.

7. A polymer according to claim 1 wherein each p is 0.

8. A polymer according to claim 1 wherein the repeat unit or repeat units of formula (I) form 50-99 mol % of the repeat units of the polymer.

9. A polymer according to claim 1 wherein the repeat unit or repeat units of formula (II) form 1-50 mol % of the repeat units of the polymer.

10. An organic electronic device comprising a polymer according to claim 1.

11. An organic electronic device comprising a polymer, wherein the device comprises adjacent first and second organic layers and wherein the second layer comprises the polymer according to claim 1.

12. An organic electronic device according to claim 10 wherein the organic electronic device is an organic light-emitting device; the first organic layer is an organic light-emitting layer disposed between an anode and a cathode; and the second organic layer is an electron-transporting layer or an electron-injecting layer disposed between the organic light-emitting layer and the cathode.

13. An ink comprising a polymer according to claim 1 dissolved in a solvent.

14. A method of forming an organic electronic device comprising adjacent first and second organic layers wherein the second layer comprises a polymer comprising a first repeat unit of formula (I) and a second repeat unit of formula (II): 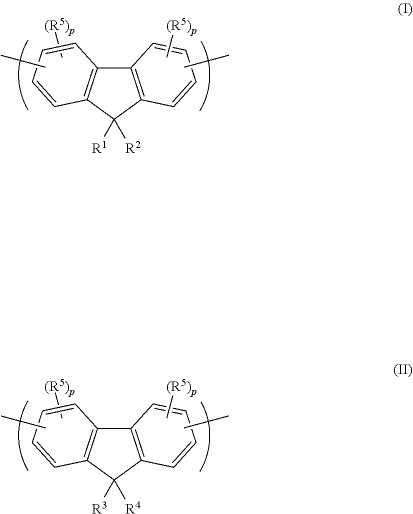
wherein
R¹ is an ionic substituent and R² is a substituent;
R³ and R⁴ are each independently a non-ionic substituent;
R⁵ independently in each occurrence is a substituent; and
each p is independently 0, 1, 2 or 3,
wherein formation of the second organic layer comprises deposition of an ink comprising the polymer dissolved in a solvent onto the first organic layer and evaporation of the solvent.

15. A light-emitting marker comprising a polymer according to claim 1 and a binding group for binding to a target analyte.

16. The light-emitting marker according to claim 15 wherein the light-emitting marker is a light-emitting particle comprising the polymer and a matrix material.

17. The light-emitting marker according to claim 15 wherein the light-emitting marker comprises a biomolecule binding group.

18. An assay method for determining the presence and/or concentration of a target analyte comprising contacting a sample with a light-emitting marker according to claim 15; irradiating the light-emitting marker with light of at least one peak wavelength; and measuring a luminance of the light-emitting marker.

19. The assay method according to claim 18 wherein the sample contacted with the light-emitting composition is analysed by flow cytometry.

20. The assay method according to claim 18 wherein the target analyte is a cell.
